(19) United States
(12) Patent Application Publication
(10) Pub. No.: US 2023/0317707 A1
(43) Pub. Date: Oct. 5, 2023

(54) INTEGRATED CIRCUIT SUBSTRATE DESIGN WITH INTEGRATED POWER CONVERTER MODULE AND METHOD OF MANUFACTURING THEREOF

(71) Applicant: NVIDIA Corporation, Santa Clara, CA (US)

(72) Inventors: Zhen Jia, Santa Clara, CA (US); Xiuzhuang Yang, Santa Clara, CA (US); Jing Guo, Santa Clara, CA (US); Yuqi Cui, Santa Clara, CA (US)

(21) Appl. No.: 18/090,708

(22) Filed: Dec. 29, 2022

(30) Foreign Application Priority Data
Mar. 29, 2022 (CN) 202210320197.1

(51) Int. Cl. H01L 25/18; H01L 23/538; H01L 23/498; H01L 25/16; H01L 23/367; H01L 21/48; H01L 25/00

(52) U.S. Cl. CPC H01L 25/18; H01L 23/5386; H01L 23/49816; H01L 23/5384; H01L 25/16; H01L 23/3672; H01L 21/486; H01L 21/4857; H01L 21/4853; H01L 25/50

(57) ABSTRACT

An integrated circuit package including a die substrate having a first and second die surfaces, a die high voltage input power connection in the die substrate to receive a high voltage input power and transmit the high voltage input power to a high voltage power trace on the first die surface, a power converter module on the first die surface and electrically connected to the high voltage power trace to convert the high voltage input power to a low voltage output power, a low voltage power trace located on the first die surface and electrically connected to the power converter module to carry the low voltage output power to a circuit die on the first die surface. A method of manufacturing the integrated circuit package and a computer having one or more circuits that include the package is also disclosed.

### CROSS-REFERENCE TO RELATED APPLICATION

This application claims priority to CN Patent Application No. 202210320197.1, entitled “AN INTEGRATED CIRCUIT SUBSTRATE DESIGN WITH INTEGRATED POWER CONVERTER MODULE AND METHOD OF MANUFACTURING THEREOF”, filed Mar. 29, 2022. The above-listed application is commonly assigned with the present application is incorporated herein by reference as if reproduced herein in its entirety.

### TECHNICAL FIELD

This application is directed, in general, to integrated circuit packages and methods of manufacturing thereof, and in particular, an integrated circuit package that includes a die-integrated power regulator module.

### BACKGROUND

Graphics processors such as graphical processing unit (GPU) dies or chips are increasingly important for high performance computing (HPC) and artificial intelligence applications. By working together, the cores of a GPU can improve computing performance especially when a processing task can be divided up and processed across many cores. To keep increasing computing performance, there is a movement towards using increasingly larger dies with more transistors per core and a higher operation clock speed.

More transistors, cores and higher working clock speeds, however, all require higher levels of power consumption. Some believe that there may soon be reached a power limitation to integrate graphics processors into computing systems, such as HPC data-center system, to improve performance. Computing systems would benefit from improved power efficiency because this would facilitate better computing performance and higher computing density. Raising the power efficiency of a circuit die is important to furthering the goal of increasing computing performance.

### SUMMARY

One aspect provides an integrated circuit package including a die substrate having a first die surface and a second die surface on an opposite side of the die substrate as the first die surface, a die high voltage input power connection in the die substrate and arranged to receive a high voltage input power and transmit the high voltage input power to a high voltage power trace located on the first die surface, a power converter module located on the first die surface and electrically connected to the high voltage power trace, wherein the power converter module converts the high voltage input power to a low voltage output power and a low voltage power trace located on the first die surface and electrically connected to the power converter module to carry the low voltage output power to a circuit die located on the first die surface.

In some embodiments, the die high voltage input power connection can include microbumps located on the second die surface and through substrate vias electrically connected to the microbumps.

In some embodiments, the high voltage input power can be in a range of about 7 to about 22 Volts and the low voltage output power can be in a range of about 0.3 to about 1.5 Volts.

In some embodiments, the low voltage power trace can have a path length from the power converter module to the circuit die that is equal to about 10 mm or shorter.

In some embodiments, the die high voltage input power connection can within a distance of about 5 to 10 mm of a perimeter of the die substrate.

In some embodiments, the microbumps of the die high voltage input power connection can be arranged as a two-by-one dimensional array adjacent to a perimeter of the die substrate.

In some embodiments, the power converter module can include a capacitor submodule, inductor submodule, and transistor submodule arranged as a vertical stack.

In some embodiments, the power converter module can be located on the first die surface between the high voltage power trace and the low voltage power trace.

In some embodiments, wherein the power convertor module can be one of a plurality of power converter modules and the power convertor modules can on the first die surface and each connected to one of a plurality of the die high voltage input power connections located adjacent to a perimeter of the die substrate.

Any such embodiments, can further include a power controller module located on the first die surface and connected to adjust the power converter module to output the low voltage output power from the high voltage input power.

Any such embodiments, can further include a thermal cooling module located on the first die surface, wherein the thermal cooling module contacts the circuit die and the power converter module.

In any such embodiments, the circuit die can be a graphics processing unit circuit die.

Any such embodiments can further include a package substrate, where the die high voltage input power connection can be connected to a high voltage power trace on a first package surface of the package substrate to carry the high voltage input power from a package input power connector to the die high voltage input power connection. In some such embodiments, the DC resistance loss across the low voltage power trace of the package substrate is less than about 0.1 Ohm. In some such embodiments, a path length of the high voltage power trace on the package substrate can equal a value in a range from about 30 to 50 mm.

Another aspect is a method of a method of manufacturing an integrated circuit package. The method include providing a die substrate having a first die surface and a second die surface on an opposite side of the die substrate as the first die surface and forming a die high voltage input power connection in the die substrate. Forming the die high voltage input power connection can include forming a high-power through-substrate via through the die substrate, forming a high voltage power trace on the first die surface, and forming a microbump on the second die surface, the microbump electrically connected to the through substrate via. The method can include forming a low-voltage power trace on the first surface of the die substrate and mounting a power converter module to the first die surface. The power converter module can be mounted such that the power convertor module is electrically connected to the high voltage power trace on the first die surface, the power convertor module is electrically connected to the low voltage power trace on the first die surface, and the power converter module converts a high voltage input power to a low voltage output power carried to the low voltage power trace. The method can include mounting a circuit die to the first die surface, where the circuit die is connected to the low voltage power trace on the first die surface.

Some such embodiments can include mounting a power controller module to the first die surface and connected to adjust the power converter module to output the low voltage output power from the high voltage input power.

Some such embodiments can include mounting a thermal cooling module on the first die surface, where the thermal cooling module contacts the circuit die and the power converter module.

Some such embodiments can include mounting the die substrate to a package substrate, where the die high voltage input power connection is electrically connected to a high voltage power trace on a first package surface of the package substrate.

Any such embodiments can further include providing a package substrate having a first package surface and a second package surface, forming a high voltage power trace on the first package surface of the package substrate and connecting a package input power connector to the high voltage power trace.

Another aspect is an integrated circuit package that includes the die substrate, the die high voltage input power connection, the power converter module, the low voltage power trace and further includes the thermal cooling module located on the first surface of the die substrate, where the thermal cooling module contacts the graphics processing unit circuit die and the power converter module, and includes a printed circuit board, where the die high voltage input power connection is connected by a high voltage through-substrate via to a high voltage power on a first printed circuit board surface to carry the high voltage input power to the die high voltage input power connection.

Another aspect is a computer having one or more circuits that include any embodiments of the integrated circuit package disclosed herein.

### BRIEF DESCRIPTION

Reference is now made to the following descriptions taken in conjunction with the accompanying drawings, in which:

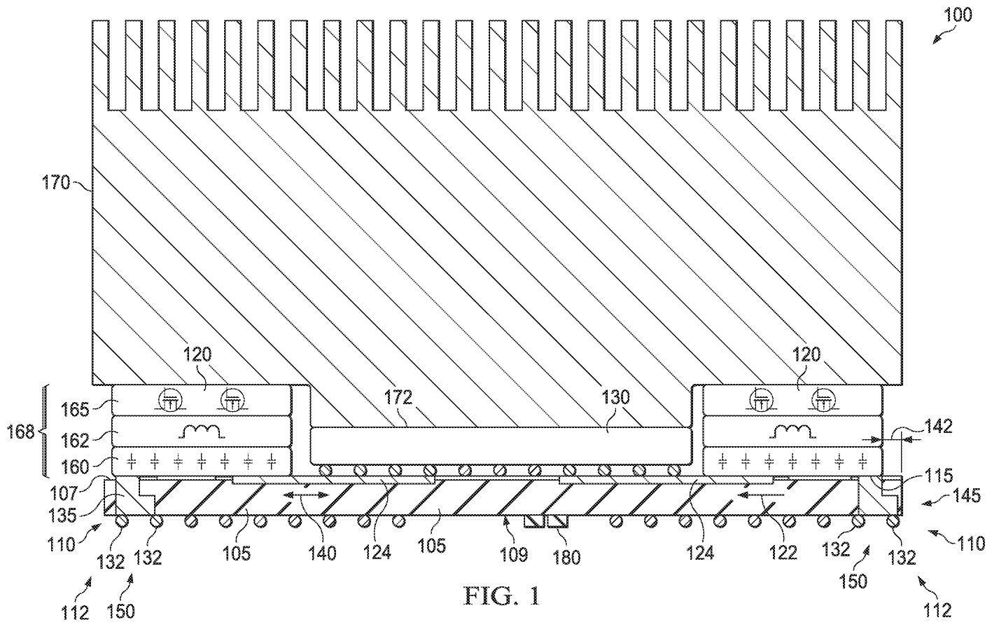

FIG. 1 presents a cross-sectional view of an example embodiment of integrated circuit package of the disclosure;

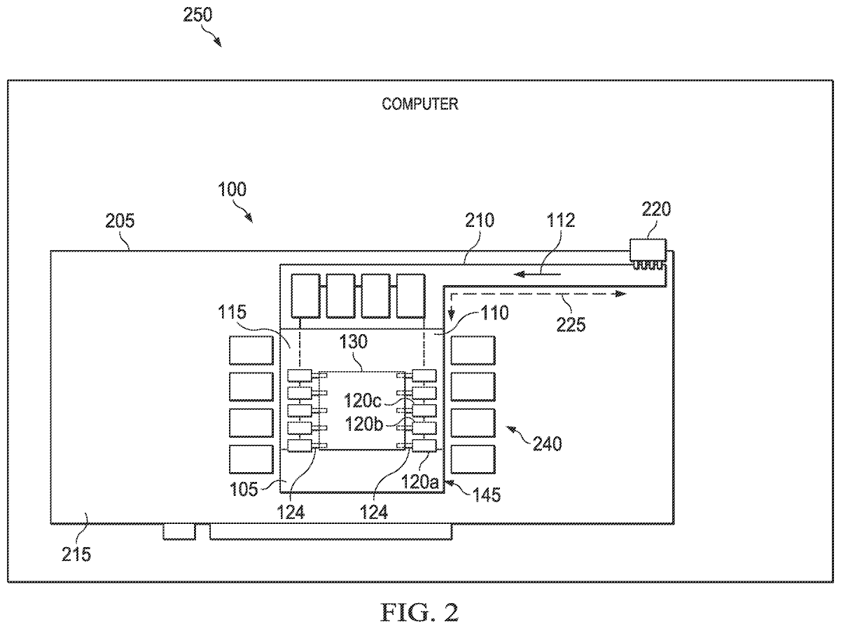

FIG. 2 presents a top down plan view of another example integrated circuit package, similar to the integrated circuit package depicted in FIG. 1, mounted to an example package substrate of the disclosure;

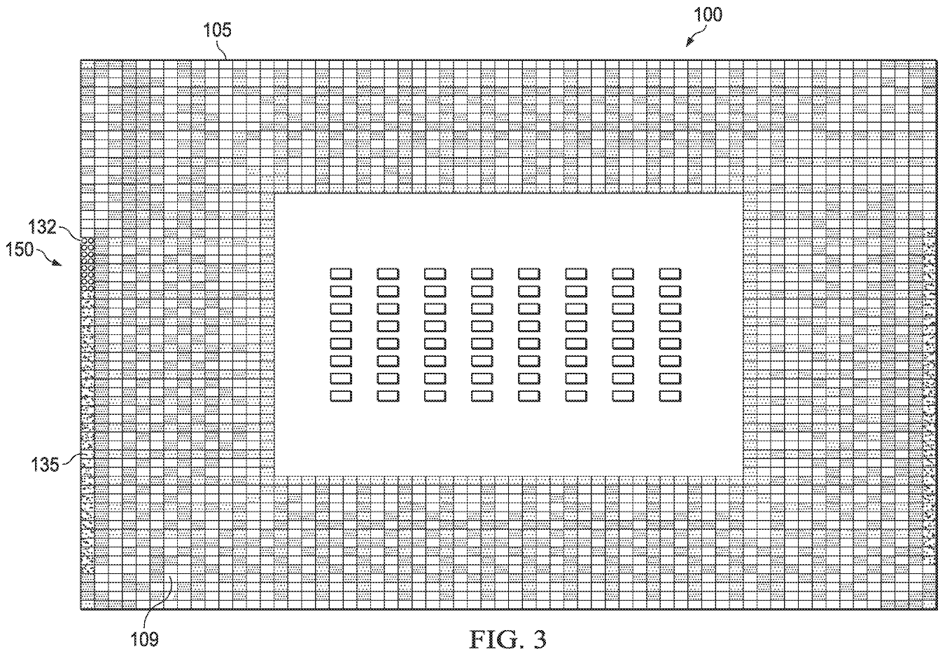

FIG. 3 presents a bottom-up plan view of another example integrated circuit package of the disclosure, similar to the integrated circuit packages depicted in FIGS. 1 and 2;

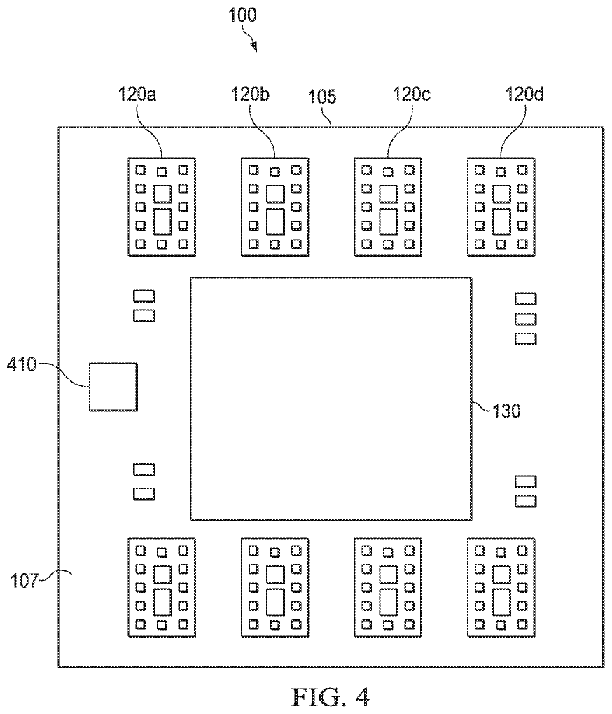

FIG. 4 presents a top-down plan view of another example integrated circuit package, similar to the integrated circuit packages depicted in FIGS. 1-3;

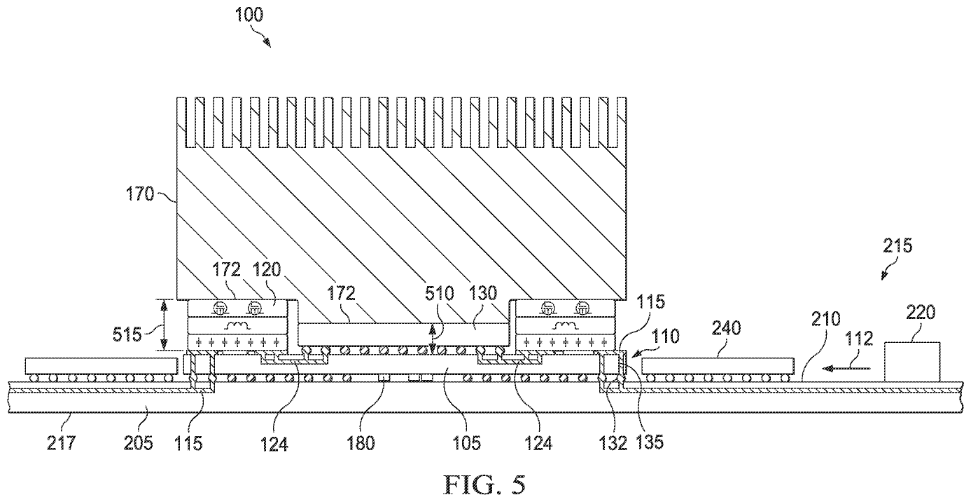

FIG. 5 presents a cross-sectional view of an example integrated circuit package of the disclosure, similar to the integrated circuit packages depicted in FIGS. 1-4, mounted to an example package substrate of the disclosure, similar to the package substrate depicted in FIG. 2; and

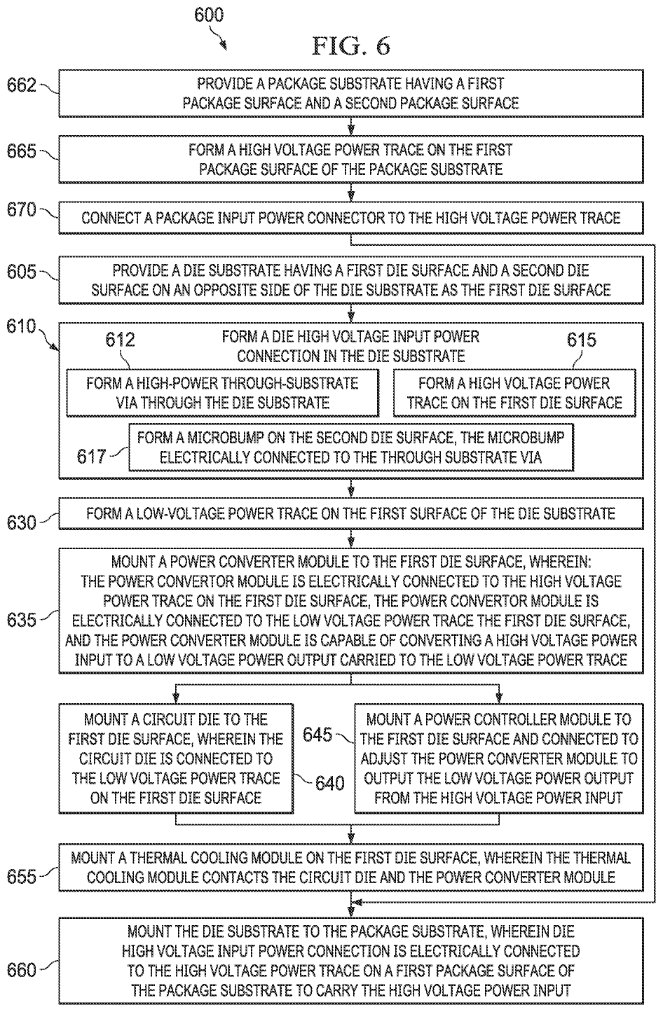

FIG. 6 presents a flow diagram of example embodiments of a method of manufacturing an integrated circuit packages according to the principles of the disclosure, including any of the packages such as disclosed in the context of FIGS. 1-5.

### DETAILED DESCRIPTION

Embodiments of the disclosure follow from our recognition of several drawbacks of existing integrated circuit packages. A higher power input current requires a larger area power plane and ground return, and more package substrate layers (e.g., printed circuit board PCB layers) for a better power distribution network (PDN) design, thereby increasing complexity and manufacturing cost of the package substrate. Power density regulators components (referred to herein as power converter modules) are often placed distant from the integrated circuit package (e.g., a GPU core, or, GPU as referred to herein) on the substrate package thereby requiring the use of a larger substrate package increased package substrate cost. Simulations done as part of the present disclosure suggest that power distribution efficiency can be lowered by about 10% due to power delivery resistance on the package substrate (e.g. due to resistance along both the substrate's input power path and GPU's core power path), which can translate into an about 10% lower GPU core performance. Thermal cooling solutions for the power converter modules located on the package substrate and the circuit die are difficult to implement. E.g., the use of thermal interface materials (TIM) is often inefficient. It can be difficult to distribute decoupling capacitors, e.g., located under the GPU, with power converter modules located on the package substrate. Larger GPU power current inputs require additional power converter modules and a larger number of solder balls for core power input (e.g., over 1000 balls) resulting in more complex solder ball and tracing designs.

To help mitigate these drawbacks, our innovation is to integrate the power regulation module onto the circuit die package with input power. This follows from our recognition that most power loss in conventional designs is caused by high current paths from the package substrate. By reducing the length of these paths from the package substrate to the circuit die, by placing high input voltage paths on the circuit die itself, power loss can be reduced. This is in contrast to previous solutions that tried to improve GPU performance per Watt of input power by improving the components parts of the power converter, e.g., by providing better metal—oxide—semiconductor field-effect transistor, MOSFET, inductor components. Such previous solutions may have had limited success because this does not address the direct current, DC, resistance of core power path from power converter's output to GPU package input and from the package substrate to the die, and the ensuing power efficiency loss.

Our new integrated circuit package design uses the substrate package's high voltage (e.g., about 12 V)/low current input power instead of low voltage (e.g., about 1 V)/high current as circuit die input. The new package design includes putting substantially more die power input routing, control signals the power converter modules and decoupling capacitors on the circuit package. Consequently, the need for multiple circuit die power input and output paths on the package substrate is substantially reduced, thereby reducing the complexity of solder ball and tracing designs. E.g., the number of solder ball arrays fir high voltage power input and out can be reduced by about an order of magnitude for some designs. E.g., the total number of solder balls, including electrical grounding balls, can similarly be reduced by about and order of magnitude for some designs. This reduction, in turn, facilitates arranging the remaining high voltage power balls layouts to reduce or avoid electrical interference by isolating the high voltage paths from signal paths, e.g. by placing high voltage power paths close to the outer perimeter of the die substrate.

One aspect of the disclosure is an integrated circuit package. FIGS. 1-5 illustrate cross-sectional and plan views the integrated circuit package 100, in accordance with the invention. With continuing reference to FIGS. 1-5, any of the package 100 embodiments can include a die substrate 105 having a first die surface 107 a second die surface 109 opposite the first die surface (e.g., a second die surface 109 on an opposite side of the die substrate 105 as the first die surface 107; in some embodiments, top and bottom die surfaces, respectively). The package 100 includes a die high voltage input power connection 110 in the die substrate 105 and the connection 110 arranged to receive a high voltage input power 112 and transmit the high voltage input power 112 to a high voltage power trace 115 located on the first die surface 107. The package includes a power converter module 120 located on the first die surface 107 and electrically connected to the high voltage power trace 115. The power converter module converts the high voltage input power 112 to a low voltage output power 122. The package 100 includes a low voltage power trace 124 located on the first die surface and electrically connected to the power converter module to carry the low voltage output power 122 to a circuit die 130 located on the first die surface 107.

The term circuit die (e.g., circuit die 130), as used herein, refers to any of a central processing unit (CPU), a graphics processing unit (GPU), or other processing cores, as familiar to those skilled in the pertinent arts, or, combinations thereof. E.g., in some embodiments the circuit die 130 is a graphics processing unit circuit die.

In some package embodiments, the die high voltage input power connection 110 includes microbumps 132 (e.g., about 100, 50, 20, 10 μm sized solder balls) located on the second die surface 109 and through substrate vias 135 electrically connected to the microbumps 132, e.g., via flip chip and solder reflow processes familiar to those skilled in the pertinent arts

In some package embodiments, the high voltage input power 112 can be in a range of about 7 to about 22 Volts and the low voltage output power 122 can be in a range of about 0.3 to about 1.5 Volts.

As used herein the term “about” signifies within ±10%, or ±1% for some embodiments, of the number recited, or other value described, as understood by person skilled in the pertinent art.

In some package embodiments, to help reduce leakage currents and power loss, the low voltage power trace 124 has a path length 140 from the power converter module 120 to the circuit die 130 that is equal to about 10 mm or shorter (e.g., about 10 mm, 5 mm, or 1 mm in some embodiments).

In some package embodiments, the microbumps 132 of the die high voltage input power connection 110 can be arranged as a two-by-one dimensional array 150 adjacent to a perimeter of the die substrate 105, e.g., to facilitate keep high voltage input power connection 110 near a perimeter 145 of the die substrate 105, and therefore help reduce interference.

In some package embodiments, to reduce current path power losses, the die high voltage input power connection 110 can be within a distance 142 of about 5 to 10 mm of a perimeter 145 of the die substrate 105.

Such embodiments can result in the distance between the power converter module 120 and the high voltage input power connection 110 being increased as compared to previous designs (e.g., about 70 to 150 mm for some embodiments as compared to about 5 to 10 mm in previous designs) but this does not present a problem of increasing DC resistance because the high voltage current can be about 1/10 of the current from previous designs.

In any package embodiments, the power converter module, or modules, can include a capacitor submodule 160, inductor submodule 162, and transistor submodule 165 arranged as a vertical stack 168, e.g., to help decrease the amount of area on the first die surface 107 occupied by the power converter module 120.

In some package embodiments, to facilitate minimizing the path length 140, or path lengths, from the power converter module, or modules, to the circuit die 130, the power converter module 120 can be located on the first die surface 107 between the high voltage power trace 115 and the low voltage power trace 124.

In some package embodiments, the power convertor module can be one of a plurality of power converter modules (e.g., modules 120a, 120b, 120c, 120d . . . , FIG. 2) and the power convertor modules can be on the first die surface 107 and each connected to one of a plurality of the die high voltage input power connections 110 located adjacent to a perimeter 145 of the die substrate 105

Any such package embodiments can further include a power controller module (e.g., FIG. 4, power converter controller 410) located on the first die surface 107 and connected to adjust the power converter module 120 to output the low voltage output power 122 from the high voltage input power 112.

One skilled in the pertinent art would be familiar with how the integrated circuit chip of the power controller module 410 could be designed to set or switch different output voltages or responses for different levels of load transient power, e.g., via pulse-width modulation (PWM) techniques using a power MOSFET device. E.g., the average value of voltage (and current) fed to the load is can be controlled by the power controller module by turning the module (e.g., a transistor of the module) to switch between supply and load, on and off, at a fast rate. The longer the module (e.g., transistor switch) is on compared to the off periods, the higher the power supplied.

Any such package embodiments can further include a thermal cooling module 170 located on the first die surface 107, the thermal cooling module contacting both the circuit die 130 and the power converter module 120 upper surfaces as illustrated in FIG. 1. That is, the circuit die 130 and the power converter module 120, or modules, can share a same thermal cooling module 170. In some embodiments such as illustrated in FIGS. 1 and 5, when the circuit die 130 and the power converter module 120 project different heights (e.g., heights 510, 515, respectively) from the first die surface 107 the mounting surface 172 of the thermal cooling module can be contoured to allow contact to both the circuit die 130 and the power converter module 120.

Any such package embodiments can further include a package substrate (e.g., FIGS. 2 and 5, package substrate 205, where the die high voltage input power connection 110 is connected to a high voltage power trace 210 on a first package surface 215 of the package substrate 205 to carry the high voltage input power 112 from a package input power connector 220 to the die high voltage input power connection 110.

In some such embodiments, to reduce power losses, the DC resistance loss across the low voltage power trace 124 of the die substrate 105 can be less than about 0.1 Ohm. For instance, in some such embodiments, the DC resistance across the low voltage core power trace changes from 0.0383 Ohm to 0.0077 Ohm, with a DC resistance loss of about 0.031 Ohm. E.g., some of our simulation results suggest that, compared to previous designs where the package substrate (PCB) power plane power loss can be about 23 W (600A), some embodiments of our new design can have a power loss reduced to about 4.6 W, resulting in a 18 W or about 5 times power saving.

In some such embodiments, a path length 225 of the high voltage power trace 210 on the package substrate 205 equals a value in a range from about 30 to 50 mm or 40 mm in some embodiments. This follows from our movements of the high voltage power traces 210 from the package substrate 205) to the die substrate 105 which in turn allows enough spacing for board input power with multi-layer and wide traces (e.g., 3 to 4 times wider as compared to traditional designs) for input power.

FIGS. 2 and 5 illustrate embodiments of the package 100 that further includes a package substrate 205 (e.g., a printed circuit board). The die high voltage input power connection 110 can be connected by a high voltage through-substrate via 135 to a high voltage power trace 115 on a first printed circuit board surface 215 to carry the high voltage input power 112 to the package input power connector 220 located on the package substrate 205.

As illustrated in FIGS. 2 and 5, some such embodiments can further include one or more memory modules 240 located on the first package surface 215 of the substrate 205. As a non-limiting example, the memory modules 240 can be or include double data rate dynamic random-access memory (DDR SDRAM), such as synchronous dynamic random-access memory (SDRAM) designed for GPU circuit dies 130.

As illustrated in FIGS. 1 and 5, some embodiments of the package 100 can further include one or more decoupling capacitors 180 on the die substrate 105, e.g., to improve electrical performance of integrated circuit package 100. In some embodiments the decoupling capacitors 180 can be located only on the second die surface 109, to make space available on the first die surface 107 for the high voltage input power connection 110, the high voltage power traces 115, the power converter modules 120 and low voltage power traces 124. In other embodiments however one of more decoupling capacitors 180 can be located on the on the first die surface 107 or on both surfaces 107, 109.

As noted embodiments of our package design can substantially reduce the complexity of solder ball and tracing designs because of the reduced need for routing core power through microbumps 132 on the second die surface 109. For example, as illustrated in FIG. 3, for some simulations of a GPU die 130 with 400 W total graphic power (TGP) requirement, due to our new package design there is a need for only 68 microbumps 132 for high voltage input power to the package 100 and a total of 120 microbump including electrical ground microbumps. In contrast, a traditional GPU package with the same TGP requirement required 608 microbumps for GPU core power and total about 1088 including electrical ground microbumps. The need for less microbumps facilitates signal fan-out, to reduce interference, and also provides space for decoupling capacitors (e.g., decoupling capacitors 180) at bottom of the die substrate (e.g., second die surface 109) instead of on the package substrate 205. Embodiments of the new design can substantially eliminate the need for need VID and voltage sense pins for voltage control, since the control signals will be connected from GPU die to power converter modules 120 located directly on die substrate 105.

Another aspect of the disclosure is a computer having one or more circuits (e.g., FIG. 2, computer 250, printed circuit board 205) that include the integrated circuit package 100. E.g., any embodiments of the integrated circuit cooling package 100 disclosed herein can be part of a computer having one or more circuits that include the package 100 thereon.

Another aspect of the disclosure is a method of manufacturing an integrated circuit package. FIG. 6 illustrates by flow diagram selected steps in a method 600 of manufacturing the integrated circuit package 100 of the discloser including the manufacture of any of the embodiments of the package 100 discussed in the context of FIGS. 1-5.

With continuing reference to FIGS. 1-5 throughout, as illustrated in FIG. 6, embodiments of the method 600 includes providing (step 605) a die substrate 105 having a first die surface 107 and a second die surface 109 on an opposite side of the die substrate as the first die surface, and, forming (step 610) a die high voltage input power connection 110 in the die substrate 105. Forming the die high voltage input power connection 110 (step 610) can include: forming (step 612) a high-power through-substrate via 135, or plurality of such vias, through the die substrate 105, forming (step 615) a high voltage power trace 115 on the first die surface 107, and forming (step 617) a microbump 132, or plurality of microbumps, on the second die surface 109, the microbump or electrically connected to the through substrate via 135 or vias. The method 600 includes forming (step 630) a low-voltage power trace 124 on the first surface 107 of the die substrate 105 and mounting a power converter module (step 635) to the first die surface 107. The power convertor module is mounted (step 635) such that the power convertor module is electrically connected to the high voltage power trace 115 on the first die surface 107, the power convertor module is electrically connected to the low voltage power trace 124 on the first die surface 107, and the power converter module converts a high voltage input power 112 to a low voltage output power 122 carried to the low voltage power trace 115.

The method 600 can include mounting (step 640) a circuit die 130 to the first die surface 107, where the circuit die is connected to the low voltage power trace on the first die surface 107.

Some embodiments of the method 600 can further include mounting (step 645) a power controller module 410 to the first die surface 107 and being connected to adjust the power converter module 120 to output the low voltage output power 122 from the high voltage input power 112.

One skilled in the pertinent art would be familiar with how to form metal traces on die substrate surfaces, and mount circuit dies, power converter modules, power controller module or other circuit components to die surfaces, e.g., using solder paste printing, gluing, dipping flux or solder paste and reflow soldering techniques.

Some embodiments of the method can further include mounting (step 655) a thermal cooling module 170 on the first die surface 107, wherein the thermal cooling module contacts the circuit die 130 and the power converter module 12.

Some embodiments of the method can further include mounting (step 660) the die substrate 105 to a package substrate 205, wherein the die high voltage input power connection is electrically connected to a high voltage power trace 210 on a first package surface 215 of the package substrate.

In any such embodiments, the method 600 can further include providing (step 662) a package substrate 205 having a first package surface 215 and a second package surface 217, forming (step 665) a high voltage power trace 210 on the first package surface 215 of the package substrate 205 and connecting (step 670) a package input power connector 220 to the high voltage power trace 210.

One skilled in the pertinent art would be familiar with how to form metal traces on package surfaces, and mounting the integrated circuit package, memory modules, decoupling capacitors other package components to package surface, e.g., using solder paste printing, flip-chip, gluing, dipping flux or solder paste and reflow soldering techniques.

Those skilled in the art to which this application relates will appreciate that other and further additions, deletions, substitutions and modifications may be made to the described embodiments.

What is claimed is:

1. An integrated circuit package, comprising:
a die substrate having a first die surface and a second die surface on an opposite side of the die substrate as the first die surface;
a die high voltage input power connection in the die substrate and arranged to receive a high voltage input power and transmit the high voltage input power to a high voltage power trace located on the first die surface;
a power converter module located on the first die surface and electrically connected to the high voltage power trace, wherein the power converter module converts the high voltage input power to a low voltage output power; and
a low voltage power trace located on the first die surface and electrically connected to the power converter module to carry the low voltage output power to a circuit die located on the first die surface.

2. The package of claim 1, wherein the die high voltage input power connection includes microbumps located on the second die surface and through substrate vias electrically connected to the microbumps.

3. The package of claim 1, wherein the high voltage input power is in a range of about 7 to about 22 Volts.

4. The package of claim 1, wherein the low voltage output power is in a range of about 0.3 to about 1.5 Volts.

5. The package of claim 1, wherein the low voltage power trace has a path length from the power converter module to the circuit die that is equal to about 10 mm or shorter.

6. The package of claim 1, wherein the die high voltage input power connection is within a distance of about 5 to 10 mm of a perimeter of the die substrate.

7. The package of claim 1, wherein the microbumps of the die high voltage input power connection are arranged as a two-by-one dimensional array adjacent to a perimeter of the die substrate.

8. The package of claim 1, wherein the power converter module includes a capacitor submodule, inductor submodule, and transistor submodule arranged as a vertical stack.

9. The package of claim 1, wherein the power converter module is located on the first die surface between the high voltage power trace and the low voltage power trace.

10. The package of claim 1, wherein the power convertor module is one of a plurality of power converter modules and the power convertor modules are on the first die surface and each connected to one of a plurality of the die high voltage input power connections located adjacent to a perimeter of the die substrate.

11. The package of claim 1, further including a power controller module located on the first die surface and connected to adjust the power converter module to output the low voltage output power from the high voltage input power.

12. The package of claim 1, further including a thermal cooling module located on the first die surface, wherein the thermal cooling module contacts the circuit die and the power converter module.

13. The package of claim 1, wherein the circuit die is a graphics processing unit circuit die.

14. The package of claim 1, further including a package substrate, wherein the die high voltage input power connection is connected to a high voltage power trace on a first package surface of the package substrate to carry the high voltage input power from a package input power connector to the die high voltage input power connection.

15. The package of claim 14, wherein the DC resistance loss across the low voltage power trace of the package substrate is less than about 0.1 Ohm.

16. The package of claim 14, wherein a path length of the high voltage power trace on the package substrate equals a value in a range from about 30 to 50 mm.

17. A method of manufacturing an integrated circuit package, comprising:
providing a die substrate having a first die surface and a second die surface on an opposite side of the die substrate as the first die surface;
forming a die high voltage input power connection in the die substrate, including:
forming a high-power through-substrate via through the die substrate,
forming a high voltage power trace on the first die surface, and
forming a microbump on the second die surface, the microbump electrically connected to the through substrate via;
forming a low-voltage power trace on the first surface of the die substrate;
mounting a power converter module to the first die surface, wherein:
the power convertor module is electrically connected to the high voltage power trace on the first die surface,
the power convertor module is electrically connected to the low voltage power trace on the first die surface, and
the power converter module converts a high voltage input power to a low voltage output power carried to the low voltage power trace; and
mounting a circuit die to the first die surface, wherein the circuit die is connected to the low voltage power trace on the first die surface.

18. The method of claim 17, further including mounting a power controller module to the first die surface and connected to adjust the power converter module to output the low voltage output power from the high voltage input power.

19. The method of claim 17, further including mounting a thermal cooling module on the first die surface, wherein the thermal cooling module contacts the circuit die and the power converter module.

20. The method of claim 17, further including mounting the die substrate to a package substrate, wherein the die high voltage input power connection is electrically connected to a high voltage power trace on a first package surface of the package substrate.

21. The method of claim 17, further including:
providing a package substrate having a first package surface and a second package surface;
forming a high voltage power trace on the first package surface of the package substrate; and
connecting a package input power connector to the high voltage power trace.

22. An integrated circuit package, comprising:
a die substrate having a first die surface and a second die surface on an opposite side of the die substrate as the first die surface;
a die high voltage input power connection in the die substrate and arranged to receive a high voltage input power and transmit the high voltage input power to a high voltage power trace located on the first die surface;
a power converter module located on the first die surface and electrically connected to the high voltage power trace, wherein the power converter module converts the high voltage input power to a low voltage output power;
a low voltage power trace located on the first die surface and electrically connected to the power converter module to carry the low voltage output power to a graphics processing unit circuit die located on the first die surface;
a thermal cooling module located on the first surface of the die substrate, wherein the thermal cooling module contacts the graphics processing unit circuit die and the power converter module; and
a printed circuit board, wherein the die high voltage input power connection is connected by a high voltage through-substrate via to a high voltage power on a first printed circuit board surface to carry the high voltage input power to the die high voltage input power connection.

23. A computer having one or more circuits that include the integrated circuit package of claim 22.
